(19) United States
(12) Patent Application Publication
(10) Pub. No.: US 2018/0277712 A1
(43) Pub. Date: Sep. 27, 2018

(54) COLOR LIGHT SOURCE STRUCTURE

(71) Applicant: SITRONIX TECHNOLOGY CORP., JHUBEI CITY (TW)

(72) Inventor: MIN-NAN LIAO, JHUBEI CITY (TW)

(21) Appl. No.: 15/935,219

(22) Filed: Mar. 26, 2018

Related U.S. Application Data
(60) Provisional application No. 62/476,000, filed on Mar. 24, 2017.

(51) Int. Cl. H01L 33/00; H01L 27/15; H01L 33/34; H01L 33/46

(52) U.S. Cl. CPC H01L 33/0041; H01L 33/46; H01L 33/34; H01L 27/156

(57) ABSTRACT

The present invention discloses a color light source structure, which comprises at least one light source and a semiconductor substrate. The at least one light source is located on the semiconductor substrate. Each light source includes a light-emitting element and a metal layer. The light-emitting element is located on the semiconductor substrate and generates a first ray and a second ray. The metal layer is located on the semiconductor substrate and reflects the second ray to give a reflection ray. The reflection ray interferes with the first ray for generating a color ray.

### REFERENCE TO RELATED APPLICATIONS

This Application is based on Provisional Patent Application Ser. No. 62/476,000, filed 24 Mar. 2017, currently pending.

### FIELD OF THE INVENTION

The present invention relates generally to a light source structure, and particularly to a color light source structure.

### BACKGROUND OF THE INVENTION

Thanks to the prevalence of spontaneous light-emission technologies in recent years, in addition to the OLED technology, the Micro LED technology has gradually become another candidate technology for replacing the LCD technology. However, the Micro LED in general is made by the different semiconductor processes, for instance the LED formed on a Sapphire substrate is combined with an IC chip made by Complementary Metal-Oxide-Semiconductor (CMOS) process, that has high cost of production. Further, multiple-color light sources, such as red, green, and blue light sources, cannot be fabricated on a single semiconductor substrate, for example, a wafer, using the current Micro LED technology. In general, the multiple-color light sources are made by the traditional process (ex: using fluorescent powders) to pre-produce the varied color LEDs, and combining these varied color LEDs. Thereby, the production cost and fabrication processes for the general Micro LED require improvements.

Accordingly, the present invention discloses a color light source structure for lowering production cost and simplifying fabrication processes, as well as improving the limitations of the general Micro LED.

### SUMMARY

An objective of the present invention is to provide a color light source structure, which makes a plurality of color light sources may be disposed on a single semiconductor substrate for emitting light of multiple colors.

Another objective of the present invention is to provide a color light source structure, which comprises at least one color light source constructed by replacing fluorescent powders using a metal layer during a semiconductor process for emitting color light.

The present invention discloses a color light source structure, which comprises at least one light source and a semiconductor substrate. The at least one light source is located on the semiconductor substrate. Each light source includes a light-emitting element and a metal layer. The light-emitting element is located on the semiconductor substrate and generates a first ray and a second ray. The metal layer is located on the semiconductor substrate and reflects the second ray to give a reflection ray. The first ray interferes with the reflection ray for generating a color ray.

The present invention discloses a color light source structure, which comprises at least one light source and a semiconductor substrate. The at least one light source is located on the semiconductor substrate. Each light source includes a first light-emitting element, a metal layer, and a second light-emitting element. The first light-emitting element is located on the semiconductor substrate and generates a first ray. The metal layer is located on the semiconductor substrate and reflects the first ray to give a reflection ray. The second light-emitting element is located on the semiconductor substrate and generates a second ray. The second ray interferes with the reflection ray for generating a color ray.

The present invention discloses a color light source structure, which comprises at least one light source and a semiconductor substrate. The at least one light source is located on the semiconductor substrate. Each light source includes a first light-emitting element, a first metal layer, a second light-emitting element, and a second metal layer. The first light-emitting element is located on the semiconductor substrate and generates a first ray. The first metal layer is located on the semiconductor substrate and reflects the first ray to give a first reflection ray. The second light-emitting element is located on the semiconductor substrate and generates a second ray. The second metal layer is located on the semiconductor substrate and reflects the second ray to give a second reflection ray. The second reflection ray interferes with the first reflection ray for generating a color ray.

The present invention discloses a color light source structure for a display device, which comprises a plurality of light sources and a semiconductor substrate. The plurality of light sources are located on the semiconductor substrate. Each light source includes a light-emitting element and a metal layer. The light-emitting element is located on the semiconductor substrate and generates a first ray and a second ray. The metal layer is located on the semiconductor substrate and reflects the second ray to give a reflection ray, and the reflection ray interferes with the first ray for generating a color ray.

The present invention discloses a color light source structure for a display device, which comprises a plurality of light sources and a semiconductor substrate, the plurality of light sources are located on the semiconductor substrate. Each light source comprises a first light-emitting element, a metal layer, and a second light-emitting element. The first light-emitting element is located on the semiconductor substrate and generates a first ray. The metal layer is located on the semiconductor substrate and reflects the first ray to give a reflection ray. The second light-emitting element is located on the semiconductor substrate and generates a second ray, and the second ray interferes with the reflection ray for generating a color ray.

The present invention discloses a color light source structure for a display device, which comprises a plurality of light sources and a semiconductor substrate, the plurality of light sources are located on the semiconductor substrate. Each light source comprises a first light-emitting element, a first metal layer, a second light-emitting element, and a second metal layer. The first light-emitting element is located on the semiconductor substrate and generates a first ray. The first metal layer is located on the semiconductor substrate and reflects the first ray to give a first reflection ray. The second light-emitting element is located on the semiconductor substrate and generates a second ray. The second metal layer is located on the semiconductor substrate and reflects the second ray to give a second reflection ray, and the second reflection ray interferes with the first reflection ray for generating a color ray, or the first reflection ray interferes with the second ray for generating the color ray.

### BRIEF DESCRIPTION OF THE DRAWINGS

The accompanying drawings are included to provide further understanding of the invention, and are incorporated into and constitute a part of this specification. The drawings illustrate embodiments of the invention and, together with the description, serve to explain the principles of the invention.

FIG. 1 shows a schematic diagram of a color light source structure according to an embodiment of the present invention;

FIG. 2 shows a schematic diagram of the circuit connection of the light-emitting element of the color light source structure according to an embodiment of the present invention;

FIG. 3 shows a schematic diagram of light generation by the color light source structure according to the first embodiment of the present invention;

FIG. 4 shows a schematic diagram of light generation by the color light source structure according to the second embodiment of the present invention;

FIG. 5 shows a schematic diagram of light generation by the color light source structure according to the third embodiment of the present invention;

FIG. 6 shows a schematic diagram of light generation by the color light source structure according to the fourth embodiment of the present invention; and

FIG. 7 shows a schematic diagram of light generation by the color light source structure according to the fifth embodiment of the present invention.

### DETAILED DESCRIPTION

In the specifications and subsequent claims, certain words are used for representing specific devices. A person having ordinary skill in the art should know that manufacturers might use different nouns to call the same device. In the specifications and subsequent claims, the differences in names are not used for distinguishing devices. Instead, the differences in techniques as whole are the guidelines for distinguishing. In the whole specifications and subsequent claims, the word “comprising” is an open language and should be explained as “comprising but not limited to”. Besides, the word “couple” includes any direct and indirect connection. Thereby, if the description is that a first device is coupled to a second device, it means that the first device is connected to the second device directly, or the first device is connected to the second device via other device or connecting means indirectly.

In order to make the structure and characteristics as well as the effectiveness of the present invention to be further understood and recognized, the detailed description of the present invention is provided as follows along with embodiments and accompanying figures.

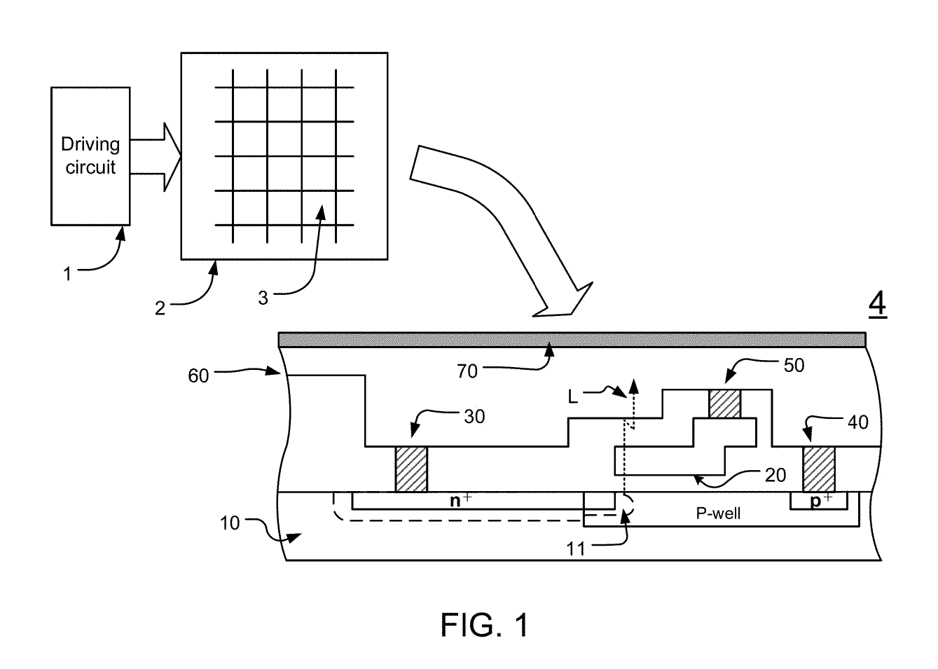

Please refer to FIG. 1, which shows a schematic diagram of a color light source structure according to an embodiment of the present invention. As shown in the figure, the display region 2 of a display device is driven by a driving circuit 1. The display region 2 includes a plurality of pixels 3. The color light source structure according to the present invention may be applied to the display region 2 and controlled by the driving circuit 1 to generate a ray L. Thereby, each pixel 3 may display an image according to the ray L generated from the at least one light source 4 of the color light source structure. The driving circuit 1 may output a driving signal to the light source 4 for controlling the light source 4 to generate the ray L. In addition, the ray L is generated by recombination and generation of electrons and holes. Hence, different voltage levels of the driving signal may control the degree of recombination and generation of electrons and holes and thus control the generation and intensity of the ray L. The color light source structure may be a structure of a plurality of light sources 4 in a single pixel 3. Alternatively, the color light source structure may be a structure of a plurality of light sources 4 for the whole display region 2. Moreover, each light source 4 of the color light source structure is located on a same semiconductor substrate 10. According to the present embodiment, the semiconductor substrate 10 may be a wafer substrate and be a transparent substrate. The material may be Silicon. Besides, the color light source structure according to the present embodiment is fabricated during the semiconductor process. In other words, the light source structure on the single semiconductor substrate 10 may emit color rays of various colors. It is not required to integrate with another semiconductor substrate having different color sources after the semiconductor process before it can emit color rays of various colors.

Furthermore, the light source 4 of the color light source structure according to the present invention may be, likewise, applied to other lighting products, such as flashlights, desk lamps, or staircase lamps, instead of limited to the light source for a display device.

Please refer again to FIG. 1, which shows a single light source 4 disposed on the semiconductor substrate 10 for description. While determining the number of the light sources 4 required for each pixel 3, the semiconductor substrate 10 may be designed to set a plurality of color light sources 4 on the semiconductor substrate 10 according to the technology of the present invention. For example, the single semiconductor substrate 10 is set to include a red light source and a green light source, or a red light source and a blue light source, or a green light source and a blue light source. This can be considered by the designer but not limited by the present invention. The light source 4 according to the embodiment in FIG. 1 includes a light-emitting element having a light-emitting zone 11. According to the present embodiment, a CMOS (Complementary Metal-Oxide-Semiconductor) process may be applied to the single semiconductor substrate 10, thus the light source 4 located on the semiconductor substrate 10 comprises the light-emitting zone 11, a poly-layer (ex: poly-Silicon layer) 20, a passivation layer 60, and a metal layer 70. The passivation layer 60 and the metal layer 70 cover the poly-layer 20.

The light-emitting zone 11 of the light-emitting element may generate the ray L and emit to the metal layer 70. The passivation layer 60 spaces the metal layer 70 and the light-emitting zone 11, in which the passivation layer 60 is made by the insulation material of Si3N2 or SiO2. Thereby, as the thickness of the passivation layer 60 increases, the gap between the metal layer 70 and the light-emitting element increases; as the thickness of the passivation layer 60 decreases, the gap between the metal layer 70 and the light-emitting element decreases. Namely, the optical path length of the ray L from the light-emitting zone 11 to the metal layer 70 varies according to the thickness of the passivation layer 60. Besides, FIG. 1 only shows one layer of the passivation layer 60 and one layer of the metal layer 70. Nonetheless, during the CMOS process, a plurality layers of passivation layers 60 and metals layers 70 may be fabricated on the light-emitting element. In other words, the light-emitting zone 11 may emit the ray L upwards to one of the plurality of metal layers 70. For example, the light-emitting zone 11 may emit the ray L to the metal layer 70 among the plurality of metal layers 70 closest to or most distant from the light-emitting element. Thereby, according to the gap between the metal layer 70 and the light-emitting element, the optical path of the ray L may be determined.

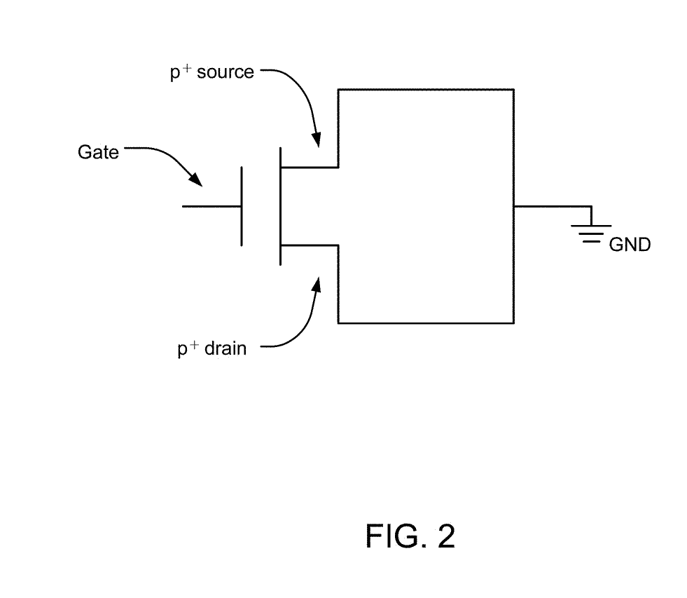

The above-mentioned light-emitting element may be various LED structures. For example, please refer to FIG. 2, which shows a schematic diagram of the circuit connection of one type of the light-emitting elements of the color light source structure according to the present invention. As shown in the figures, a source (p⁺ source) and a drain (p⁺ drain) of a PMOS element are coupled to a ground GND, respectively. Further, a positive voltage is supplied to an N-type substrate thereof, thus the PMOS element has a P-N junction with a reverse-biased operated as LED, in which the gate of the PMOS element may be keep floated or may be supplied with a suitable bias voltage to control the operation of the PMOS element. Besides, according to FIG. 1, an n-type doping region n+ is formed under the first metal part 30; a p-type doping region p+ is formed under the second metal part 40; the p-type doping region p+ may be formed in a P-well; thus the light-emitting zone 11 is formed between the n-type doping region n+ and the p-type doping region p+. This light-emitting zone 11 is a space charge region, which is the region for recombination and generation of electrons and holes. Further, the suitable bias voltage is supplied to a gate via a third metal part 50, the gate is formed at the poly-layer 20 and between the n-type doping region n+ and the p-type doping region p+, to control the operation of this light-emitting element. In addition, all of the above-mentioned various LEDs may be fabricated by CMOS process.

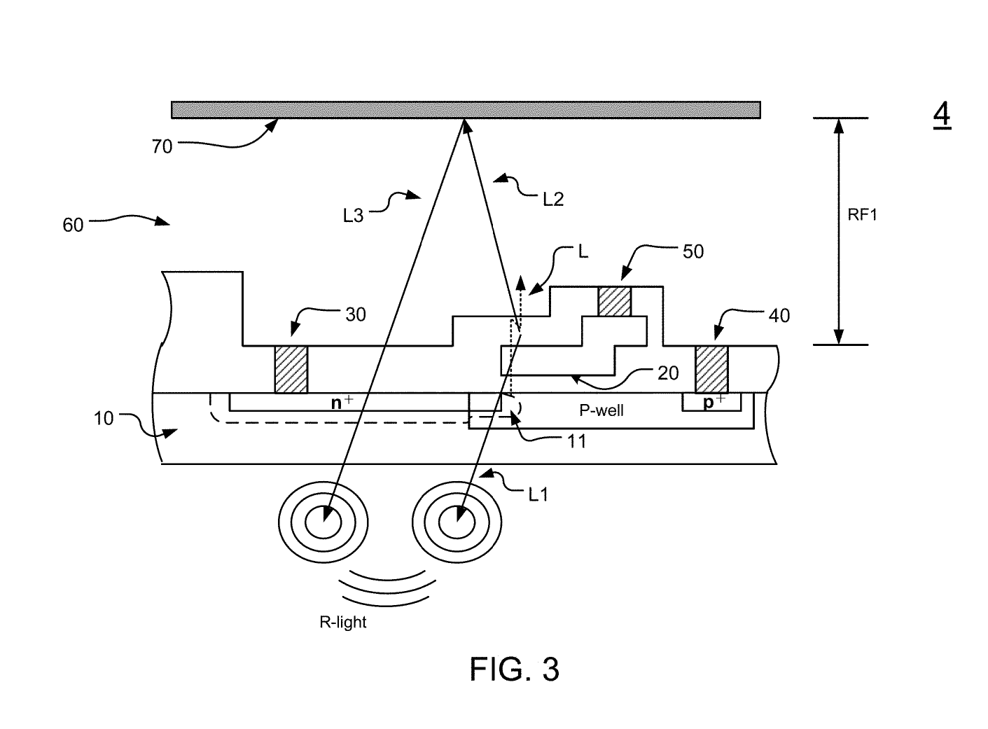

Please refer to FIG. 3, which shows a schematic diagram of light generation by the color light source structure according to the first embodiment of the present invention. As shown in the figure, the light source 4 is located on the semiconductor substrate 10 and generates a first ray L1 and a second ray L2. The light-emitting element of the light source 4 emits the first ray L1 beneath the light-emitting element along a first optical path and emits the second ray L2 to the metal layer 70 along a second optical path. For reducing the influences on the first ray L1 and the second ray L2, the location of the second optical path of the second ray L2 passing through the passivation layer 60 may be thinned or holed, and, likewise, the location of the first optical path of the first ray L1 passing through the semiconductor substrate 10 may be holed or thinned. Further, the thickness of the passivation layer 60 or/and the semiconductor substrate 10 may be increased for decreasing the intensity of the first ray L1 and the second ray L2.

Furthermore, the metal layer 70 reflects the second ray L2 to give a reflection ray L3 passes along a third optical path. After the reflection ray L3 passes along the third optical path and through the passivation layer 60, the poly-layer 20, and the semiconductor substrate 10, it interferes with the first ray L1 for generating a color ray. According to the embodiment of FIG. 3, the color ray is a red ray R-light. In other words, the light source 4 fabricated on the semiconductor substrate 10 of FIG. 3 may be a red light source. Please refer again to FIG. 3. The first ray L1 and the reflection ray L3 are initially the same color rays (ex: white color ray or other color rays). Compared with the optical path of the first ray L1 and the reflection ray L3, the optical path of the reflection ray L3 includes an extra reflection distance RF1. Thereby, the optical path (the second optical path and the third optical path) of the reflection ray L3, which can act as the second ray L2 as well, is approximately the distance from the light-emitting element to the metal layer 70 and from the metal layer 70 to the interference place with the ray L1. The optical path (the first optical path) of the first ray L1 is only from the light-emitting element to the interference place with the reflection ray L3. Namely, compared to a length of the first optical path of the first ray L1, a length of the third optical path plus the second optical path of the reflection ray L3 includes an additional optical path length. Hence, according to the present invention, by using the metal layer 70 fabricated on the semiconductor substrate 10, the second ray L2 is reflected to give the reflection ray L3 to interfere with the first ray L1, thus the first ray L1 and the reflection ray L3 having different optical path lengths to generate a color ray by interference. In addition, the color of the color ray is different from the color of the first ray L1. The above-mentioned first, second, and third optical paths are different optical path.

Accordingly, the present invention makes use of the interference of two rays having optical path difference to generate the color ray. As described above, the optical path difference may be adjusted by using the thickness of the passivation layer 60 shown in FIG. 1. Namely, the reflection distance RF1 in FIG. 3 varies as the thickness of the passivation layer 60 varies. Besides, when a plurality of passivation layers 60 and a plurality of metal layers 70 located on the light-emitting element, the different metal layer 70, where a metal layer may be called as a reflection layer, may reflect the second ray L2. It is not limited that the reflection may occur on the metal layer 70 closest to the light-emitting element, as shown in FIG. 3. Thereby, the metal layer 70 not used as the reflection layer may have some avoidance design in layout, such as holes. Contrarily, the plurality of passivation layers 60 between the light-emitting element and the metal layer 70 used as the reflection layer may be used for adjusting the reflection distance RF1. In addition, in a display device or a handheld lighting product, if the space of the structure is sufficient, the reflection ray L3, which is the primary reflection of the second ray L2, interferes with the first ray L1 for generating the color ray. In other words, once the gap between the metal layer 70 and the light-emitting element, that affects the reflection distance RF1, is large enough, after the second ray L2 is reflected by the metal layer 70 once and giving the reflection ray L3, the reflection ray L3 may be used for interference and generating the color ray. Alternatively, the plurality of metal layers 70 located on the semiconductor substrate 10 may be used for reflecting the second ray L2 for multiple times for interference and generating the color ray.

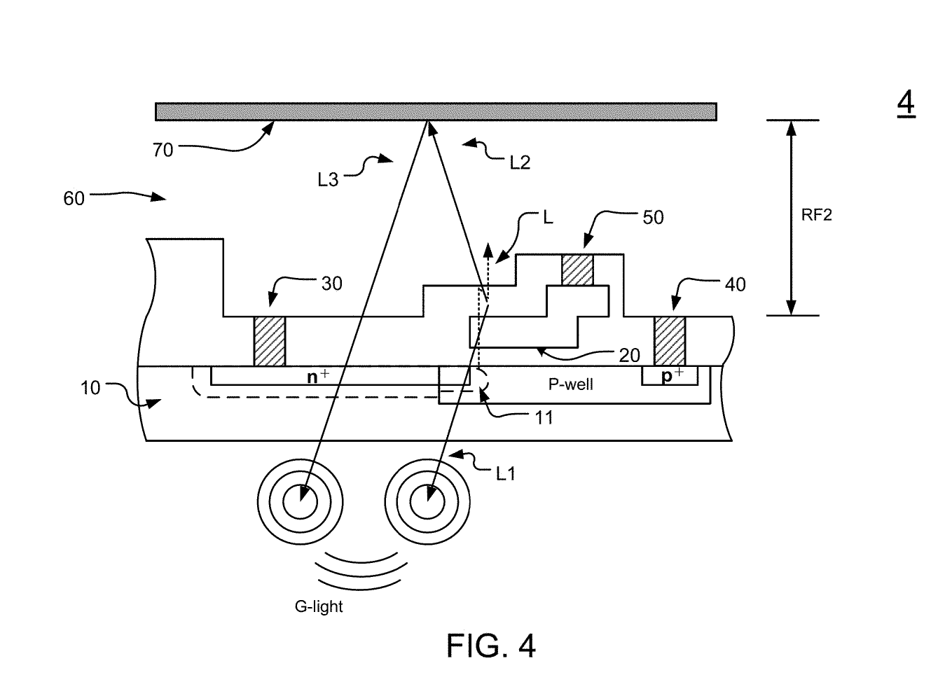

Please refer to FIG. 4, which shows a schematic diagram of light generation by the color light source structure according to the second embodiment of the present invention. As shown in the figure, the gap between the metal layer 70 and the light-emitting element shown in FIG. 4, namely, the reflection distance RF2, is shorter than the gap between the metal layer 70 and the light-emitting element shown in FIG. 3, namely, the reflection distance RF1. After the reflection ray L3 according to the embodiment of FIG. 4 interferes with the first ray L1, a green ray G-light is generated. In other words, after varying the optical path difference between the reflection ray L3 and the first ray L1, the light source 4 may emit color rays with different colors. The color light source structures shown in FIGS. 3 and 4, including the red light source and the green light source, may be simultaneously fabricated on the single semiconductor substrate 10 directly by CMOS process. No fluorescent powder is required and hence reducing the manufacturing cost and simplifying the fabrication processes, moreover, by adjusting the gap between the light-emitting element and the metal layer 70, the purpose of generating rays of different colors may be achieved.

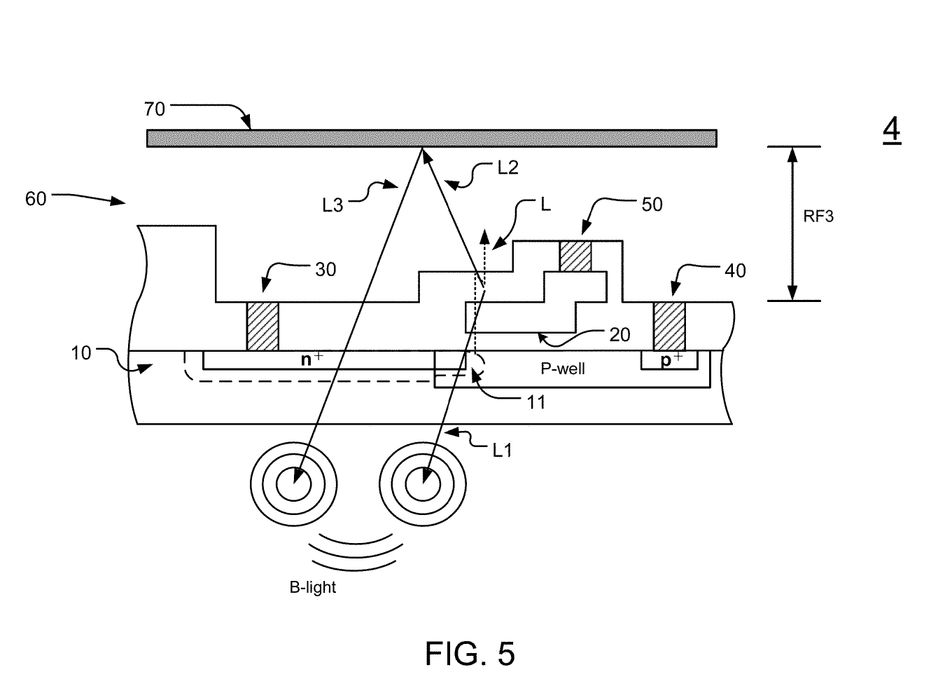

Furthermore, according to the embodiments in FIGS. 3 and 4, the color light source structure according to the present invention may comprise at least white light source, red light source, and green light source on the single semiconductor substrate 10 and hence broadening the application of the Micro-LED technology. Likewise, the blue light source may also be provided on the single semiconductor substrate 10, as shown in FIG. 5. In this case, the gap between the metal layer 70 and the light-emitting element, namely, the reflection distance RF3, is further shortened for interference and generating a blue ray B-light. In other words, for the three light sources 4 on the single semiconductor substrate 10, the gaps between the metal layer 70 and the light-emitting element are different, such as the first gap, the second gap, and the third gap. Thereby, three color light sources, R, G, B are disposed on the single semiconductor substrate 10. Nonetheless, the number and the type of the light sources on a single semiconductor substrate 10 may be planned according to requirement. The present invention is not limited by specific number and type.

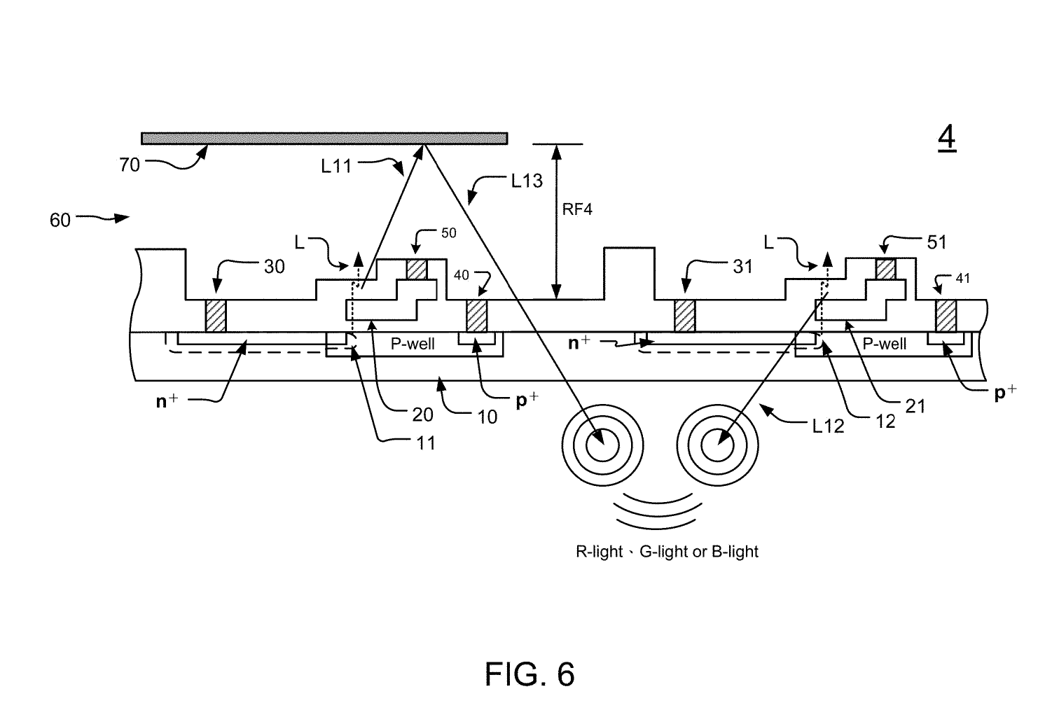

The preferred distances for the reflection distances RF1, RF2, RF3 in the red, greed, and blue light sources are 544˜816 nm, 424˜636 nm, and 352˜582 nm, respectively; however, it should be appropriately adjusted for an emitted angle of ray and the reflection times of ray on the metal layer 70. In addition, two rays having an optical path difference may interfere to generate color rays. Thereby, as shown in FIG. 6, when a plurality of light-emitting elements is disposed on the single semiconductor substrate 10, the first light-emitting element on the left side emits the first ray L11 passing along the first optical path to the metal layer 70. The metal layer 70 reflects the first ray L11 to give the reflection L13 passing along the second optical path. Afterwards, the reflection ray L13 interferes with the second ray L12 emitted passing along the third optical path from the second light-emitting element on the right side for generating the red ray, the green ray, or the blue ray. The first, second, and third optical paths are different optical paths, and a length of the second optical path plus the first optical path differs from a length of the third optical path by an optical path length. As described above, the reflection distance RF4 may make the optical path length of the reflection ray L13 (the first ray L11) different from the optical path length of the second ray L12 and hence the interference is possible to give rays of different colors.

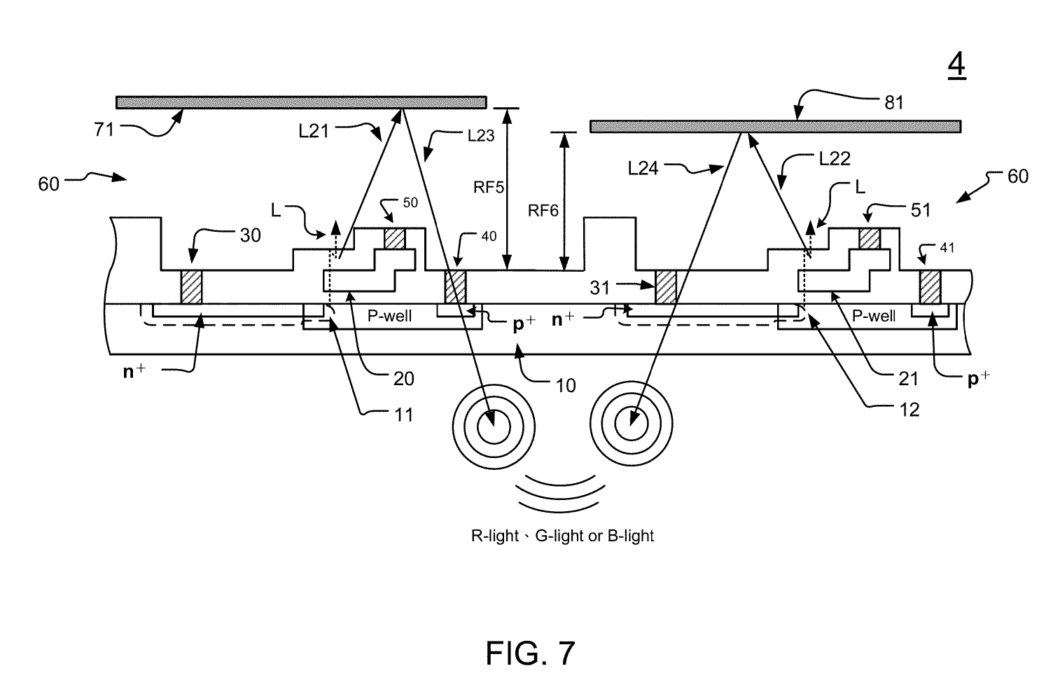

Moreover, as shown in FIG. 7, a first light-emitting element on left side and a second light-emitting element on right side are disposed on the single semiconductor substrate 10. The gap between the first metal layer 71 and the first light-emitting element on left side is the reflection distance RF5 (first gap). The gap between the second metal layer 81 and the second light-emitting element on right side is the reflection distance RF6 (second gap). The reflection distance RF6 is different from the reflection distance RF5. The two light-emitting elements disposed on the single semiconductor substrate 10 emit the first and second rays L21, L22 passing along the first optical path and the third optical path to the corresponding metal layers 71, 81, respectively, the first and second metal layers 71, 81 reflect the first and second rays L21, L22 and giving the first and second reflection rays L23, L24 passing along the second optical path and the fourth optical path, respectively. Further, the first, second, third, and fourth optical paths are different optical paths. The length of the second optical path plus the first optical path differs from the length of the fourth optical path plus the third optical path by an optical path length. After the first and second reflection rays L23, L24 pass through the respective light-emitting elements, interference occurs, generating the red ray, the green ray, or the blue ray. Further, a gap difference between the reflection distance RF5 and the reflection distance RF6 determines the color ray to be the blue ray, the green ray, or the red ray. The rest technology is the same as the above description, Hence, the details will not be described again.

The color light source structure according to the present invention may be applied to the display device. Thereby, the color light source structure may include three light sources, for example, red light source, green light source, and blue light source for generating the red ray, the green ray, and the blue ray.

To sum up, the present invention discloses a color light source structure, which comprises a plurality of light sources of various colors and a semiconductor substrate. The light sources are located on the semiconductor substrate. Each light source includes a light-emitting element and a metal layer. The light-emitting element is located on the semiconductor substrate and generates a plurality of rays. The metal layer is located on the semiconductor substrate and reflects a part of the rays to give a reflection ray. The reflection ray and/or the ray having the different optical path lengths interfere for generating a color ray. In addition, according to the embodiments shown in FIGS. 3 to 7, the present invention makes use of the metal layer disposed on the semiconductor substrate to create optical path difference between two rays for interference and generating the color ray. Thereby, the two interfering rays are not limited to the original ray (as the first ray L1) of the light-emitting element and the reflection ray L3. Instead, any two rays having optical path difference may be used for interference and generating color rays of various colors, as the embodiments shown in FIG. 6 and FIG. 7.

Various aspects of the disclosure have been described above. It should be apparent that the teachings herein may be embodied in a wide variety of forms and that any specific structure, function, or both being disclosed herein is merely representative. Based on the teachings herein one skilled in the art should appreciate that an aspect disclosed herein may be implemented independently of any other aspects and that two or more of these aspects may be combined in various ways. For example, a structure may be implemented or a method may be practiced using any number of the aspects set forth herein. In addition, such a structure may be implemented or such a method may be practiced using other structure, functionality, or structure and functionality in addition to or other than one or more of the aspects set forth herein.

It is understood that any specific order or hierarchy of steps in any disclosed process is an example of a sample approach. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

While the invention has been described in connection with various aspects, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A color light source structure, comprising at least one light source and a semiconductor substrate, said at least one light source located on said semiconductor substrate, and each said light source comprising:
a light-emitting element, located on said semiconductor substrate, and generating a first ray and a second ray; and
a metal layer, located on said semiconductor substrate, reflecting said second ray to give a reflection ray, and said reflection ray interfering with said first ray for generating a color ray.

2. The color light source structure of claim 1, wherein said light-emitting element emits said first ray and said second ray along a first optical path and a second optical path, respectively; said metal layer reflects said second ray to give said reflection ray along a third optical path; said first optical path, said second optical path, and said third optical path are different optical paths; a length of said third optical path plus said second optical path differs from a length of said first optical path by an optical path length; and the color of said color ray is different from the color of said first ray.

3. The color light source structure of claim 1, wherein said color ray is a blue ray, a green ray, or a red ray depending on the distance between said metal layer and said light-emitting element being a first gap, a second gap, or a third gap, respectively.

4. The color light source structure of claim 1, wherein a poly-layer, a passivation layer, and said metal layer are disposed on said semiconductor substrate; said passivation layer and said metal layer cover said poly-layer.

5. A color light source structure, comprising at least one light source and a semiconductor substrate, said at least one light source located on said semiconductor substrate, and each said light source comprising:
a first light-emitting element, located on said semiconductor substrate, and generating a first ray;
a metal layer, located on said semiconductor substrate, and reflecting said first ray to give a reflection ray; and
a second light-emitting element, located on said semiconductor substrate, generating a second ray, and said second ray interfering with said reflection ray for generating a color ray.

6. The color light source structure of claim 5, wherein said first light-emitting element emits said first ray along a first optical path; said metal layer reflects said first ray to give said reflection ray along a second optical path; said second light-emitting element emits said second ray along a third optical path; said first optical path, said second optical path, and said third optical path are different optical paths; a length of said second optical path plus said first optical path differs from a length of said third optical path by an optical path length; and the color of said color ray is different from the color of said first ray.

7. The color light source structure of claim 5, wherein said color ray is a blue ray, a green ray, or a red ray depending on the distance between said metal layer and said first light-emitting element being a first gap, a second gap, or a third gap, respectively.

8. A color light source structure, comprising at least one light source and a semiconductor substrate, said at least one light source located on said semiconductor substrate, and each said light source comprising:
a first light-emitting element, located on said semiconductor substrate, and generating a first ray;
a first metal layer, located on said semiconductor substrate, and reflecting said first ray to give a first reflection ray;
a second light-emitting element, located on said semiconductor substrate, and generating a second ray; and
a second metal layer, located on said semiconductor substrate, reflecting said second ray to give a second reflection ray, and said second reflection ray interfering with said first reflection ray for generating a color ray.

9. The color light source structure of claim 8, wherein said first light-emitting element emits said first ray along a first optical path; said first metal layer reflects said first ray to give said first reflection ray along a second optical path; said second light-emitting element emits said second ray along a third optical path; said second metal layer reflects said second ray to give said second reflection ray along a fourth optical path; said first optical path, said second optical path, said third optical path, and said fourth optical path are different optical paths; a length of said second optical path plus said first optical path differs from a length of said fourth optical path plus said third optical path by an optical path length; and the color of said color ray is different from the colors of said first ray and said second ray.

10. The color light source structure of claim 8, wherein said color ray is a blue ray, a green ray, or a red ray depending on a first gap between said first metal layer and said first light-emitting element and a second gap between said second metal layer and said second light-emitting element; a difference between said first gap and said second gap determines said color ray being said blue ray, said green ray, or said red ray.

11. A color light source structure for a display device, comprising a plurality of light sources and a semiconductor substrate, said plurality of light sources located on said semiconductor substrate, and each said light source comprising:
a light-emitting element, located on said semiconductor substrate, and generating a first ray and a second ray; and
a metal layer, located on said semiconductor substrate, reflecting said second ray to give a reflection ray, and said reflection ray interfering with said first ray for generating a color ray.

12. The color light source structure for a display device of claim 11, wherein said light-emitting element emits said first ray and said second ray along a first optical path and a second optical path, respectively; said metal layer reflects said second ray to give said reflection ray along a third optical path; said first optical path, said second optical path, and said third optical path are different optical paths; a length of said third optical path plus said second optical path differs from a length of said first optical path by an optical path length; and the color of said color ray is different from the color of said first ray.

13. The color light source structure for a display device of claim 11, comprising three light sources, said light-emitting element of each said light source distant from said metal layer by a gap, and said gaps of said three light sources being different for generating said color ray of various colors.

14. A color light source structure for a display device, comprising a plurality of light sources and a semiconductor substrate, said plurality of light sources located on said semiconductor substrate, and each said light source comprising:
a first light-emitting element, located on said semiconductor substrate, and generating a first ray;
a metal layer, located on said semiconductor substrate, and reflecting said first ray to give a reflection ray; and
a second light-emitting element, located on said semiconductor substrate, generating a second ray, and said second ray interfering with said reflection ray for generating a color ray.

15. The color light source structure for a display device of claim 14, wherein said first light-emitting element emits said first ray along a first optical path; said metal layer reflects said first ray to give said reflection ray along a second optical path; said second light-emitting element emits said second ray along a third optical path; said first optical path, said second optical path, and said third optical path are different optical paths; a length of said second optical path plus said first optical path differs from a length of said third optical path by an optical path length; and the color of said color ray is different from the color of said first ray.

16. The color light source structure for a display device of claim 14, comprising three light sources, said first light-emitting element of each said light source distant from said metal layer by a gap, and said gaps of said three light sources being different for generating said color ray of various colors.

17. A color light source structure for a display device, comprising a plurality of light sources and a semiconductor substrate, said plurality of light sources located on said semiconductor substrate, and each said light source comprising:
a first light-emitting element, located on said semiconductor substrate, and generating a first ray;
a first metal layer, located on said semiconductor substrate, and reflecting said first ray to give a first reflection ray;
a second light-emitting element, located on said semiconductor substrate, and generating a second ray; and
a second metal layer, located on said semiconductor substrate, reflecting said second ray to give a second reflection ray, and said second reflection ray interfering with said first reflection ray for generating a color ray.

18. The color light source structure for a display device of claim 17, wherein said first light-emitting element emits said first ray along a first optical path; said first metal layer reflects said first ray to give said first reflection ray along a second optical path; said second light-emitting element emits said second ray along a third optical path; said second metal layer reflects said second ray to give said second reflection ray along a fourth optical path; said first optical path, said second optical path, said third optical path, and said fourth optical path are different optical paths; a length of said second optical path plus said first optical path differs from a length of said fourth optical path plus said third optical path by an optical path length; and the color of said color ray is different from the colors of said first ray and said second ray.

19. The color light source structure for a display device of claim 17, comprising three light sources, said first light-emitting element and said second light-emitting element of each said light source distant from said first metal layer and said second metal layer by a first gap and a second gap, respectively; a gap difference between said first gap and said second gap determines the color of said color ray, and said gap differences of said three light sources are different for generating said color ray of various colors.
